(19) United States
(12) Patent Application Publication
(10) Pub. No.: US 2019/0268985 A1
(43) Pub. Date: Aug. 29, 2019

(54) LED CONTROLLER SYSTEM AND METHOD

(71) Applicant: Custom Molded Products, LLC, Newnan, GA (US)

(72) Inventor: Karthik Hosavaranchi Puttaraju, Peachtree City, GA (US)

(73) Assignee: Custom Molded Products, LLC, Newnan, GA (US)

(21) Appl. No.: 16/205,192

(22) Filed: Nov. 29, 2018

Related U.S. Application Data
(63) Continuation of application No. 29/623,937, filed on Oct. 27, 2017, now Pat. No. D838677.

(51) Int. Cl. H05B 33/08; H02M 5/458; H02M 1/08; H05K 7/20

(52) U.S. Cl. CPC H05B 33/0818; H05B 33/0887; H05K 7/209; H02M 1/083; H02M 5/4585

(57) ABSTRACT

A power supply board of the present disclosure substantially mitigates the risk of a reverse-wired lead and switch hot from the power source to the power supply board in a hazardous water-based scenario. In one exemplary embodiment, the present disclosure provides a power supply board (and a final, resulting LED controller) configured to be structurally adapted to control the load via a microcontroller and a high-power consumption switch, and to turn on and off the 120V AC power source with any duty cycle, wherein the timing at which the switch is activated is controlled to occur during a period of low voltage pressure on the negative side of the AC input voltage sine wave. All this without compromising the competing functions of the power supply board and/or the resulting LED controller.

### BACKGROUND OF THE INVENTION

### Field of the Invention

The present invention generally relates to a power supply driver circuit for solid-state lighting and, more specifically, to a power supply board for a controller for a light-emitting-diode (LED) lighting array for a pool, spa, or landscape thereof. In particular, the present invention relates to an illumination system and method of powering and controlling the electronic circuits thereof.

### Related Art

Light-emitting-diode (LED) lighting arrays are used in numerous types of pool, spa, and related landscape lighting applications. In particular, solid-state lighting panels comprising solid-state arrays of LEDs are used for direct illumination, e.g., architectural or accent lighting, of the pool, the spa, or the landscape thereof. The LEDs may be controlled via a connected controller to output various signals, which ultimately result in a specific light show from the LED(s).

Known systems and methods for accomplishing such light shows comprise turning alternating current (AC) power from a main supply line on and off with an AC switch. Further, power is conventionally delivered in AC form which, therefore, commonly necessitates (due to high voltage requirements, in some applications) a transformer and an AC/DC converter.

Other known systems and methods for a more complex light show comprises a microcontroller circuit configured to output pulse-width modulated (PWM) signals to the LEDs. In such a system and method, LEDs of various colors are required, and the PWM signals control the output of the LEDs to produce various colors and effects for the light show(s).

Other known systems and methods relate to a specialized lighting system arranged in a network. Such a system can provide coordinated color-changing lighting effects. Of course, there also are specialized lighting systems that are not associated with a network. In particular, there are lighting applications in which it may be desirable to coordinate the light output of multiple light sources that are not necessarily configured in, or readily configurable for, a network interface.

In one non-limiting example, all the non-networked light sources illuminating the pool landscape and perimeter are controlled such that they are, respectively, simultaneously energized to exhibit a color wash effect, i.e., to have the same color at any one time, but continually changing at a particular rate (e.g., energized to provide the following sequence: red to orange to yellow to green to blue to orange, etc.). When energized, all the light sources may initiate the same state, and the color wash may seem synchronized to an observer. This is especially true if the color wash speed is relatively slow and the duration of the cycle through the wash is significant.

The appearance to an observer is deceiving, as there usually is no coordinating signal to ensure that the non-networked light sources are, in fact, synchronized. In this non-limiting example, the specialized lighting system depends on the internal clocks of the independent microcontroller circuits of each light source remaining synchronized, and on some triggering event to energize the lights, typically a power-on. Ultimately, however, the independent microcontroller circuits come out of phase with one another and no longer appear synchronous.

In the prior art, this is commonly due to drift in the timing elements. These elements are subject to manufacturing process variations, temperature variations, etc. It should be appreciated that the above discussion of a “color-wash” lighting effect is for purposes of illustration only, and that any of a variety of lighting effects may be employed.

Returning generally to light sources, and in particular, to LEDs, the spectrum of light from a LED is directly related to the current flowing to the LED. When the LED is powered and illuminated, it operates at a specified current to emit the desired optical spectrum. The average output from the LED is controlled by the PWM of the current flowing to the LED. As such, the LED operates at either the specified current or zero current at a duty ratio according to the PWM to achieve the desired output. Complications in providing power from a single power supply to multiple LEDs, wherein each LED is emitting a different color at a different point in time, for example, include (1) each LED may typically operate at a different voltage dependent on the operating temperature, etc., and (2) the desired spectrum from each color LED is obtained typically at a different operating current, etc.

In one generalized example, a known specialized lighting system comprises: (1) a plurality of LEDs, possibly on a shared platform, (2) a power supply board, and (3) a processor. This processor is to independently control the output of the LEDs, to generate the PWM signals to control the LEDs, and to control the other circuitry needed to control the output of the LEDs. As such, the lighting system may be provided with a plurality of LEDs, and the processor may control the output of the LEDs such that the light from the LEDs combine to produce a light show or a progression of light shows.

However, in this one example, as in other prior art examples, there is a risk that a user might reverse the wiring of the lead (hot) and the switch hot (sw hot) of a 120 VAC (60 Hz) power source, for example, which may cause damage to the rest of the electrical components off of the power supply board, and which may create hazard to the user and those around the system. As the applications for the system (a pool, a spa, or the surrounding landscape) may involve water, or a vessel for a conductive fluid, and lighting arrays drawing up to 300 watts, in aggregate, these issues are magnified.

It would be preferable to have a specialized lighting system for non-networked light sources that is designed such that, if wired in reverse, the system will not turn-on and will handle the reversed polarity. There is, therefore, a need in the art for a LED controller and, in particular, a power supply board that can solve these issues and balance the competing functions described above. Accordingly, there is now provided with this disclosure an improved LED controller via an improved power supply board.

### BRIEF SUMMARY OF THE INVENTION

Certain exemplary embodiments of the present invention provide a power supply board that substantially mitigates the risk of a reverse-wired lead and switch hot from the power source to the power supply board in a hazardous water-based scenario. In one illustrative example, the present disclosure provides a power supply board configured to control a load via a microcontroller and a high-power consumption switch, and to turn on and off the 120V AC power source with any duty cycle, wherein the timing at which the switch is activated is controlled to occur during a period of low voltage pressure on the negative side of the AC input voltage sine wave.

In another illustrative example, a power supply board for a pool or spa-lighting application is described that can turn on/off a 120V AC input voltage source with any duty cycle. The power supply board comprises an input voltage circuit, a load output circuit, a microcontroller, a high-power consumption switch comprising one or more metal-oxide semiconductor field-effect transistors (MOSFETS); and a heat sink. It is envisioned that the microcontroller is configured to control the load, via activation of the MOSFETS of the high-power consumption switch, as a switch protection circuit. Further, the timing at which the MOSFETS are activated is controlled to occur during a period of low voltage pressure on a negative side of an AC input voltage sine wave. Further, it also is envisioned that the heat sink is in direct thermal communication with the high power consumption switch to handle any possible thermal issues.

In another illustrative example, a power supply board for a pool or spa-lighting application is described wherein the high-power consumption switch comprises at most two MOSFETS.

In another illustrative example, a power supply board for a pool or spa-lighting application is described wherein the power supply board mitigates the risk of a reverse-wired lead and switch hot, from the input voltage source to the power supply board, and wherein, when the lead and the switch hot are not connected in reverse, the AC input sine wave positive and negative are correctly passed through the MOSFETS of the high-power consumption switch to the switch hot to the load. This is accomplished by preventing boot-up of the light controller system when the lead and switch hot are connected to the input voltage circuit in reverse, for example.

In another illustrative example, a power supply board for a pool or spa-lighting application is described that additionally comprises an AC to DC convertor circuit, a DC to DC convertor circuit, a zero cross detect (ZCD) module, and/or a plurality of capacitors. It is envisioned that if the lead and the switch hot are not connected appropriately, a first capacitor is charged in a first half signal of the AC input voltage sine wave, and a second capacitor is charged in a first cycle of the AC input voltage sine wave. Further, it is envisioned that the first capacitor may be communicatively coupled to the one or more MOSFETS and configured to activate the one or more MOSFETS, and the second capacitor is communicatively coupled to the microcontroller, for running the microcontroller to choose a duty cycle of the one or more MOSFETS.

In another illustrative example, a power supply board for a pool or spa-lighting application is described wherein, when the first capacitor is discharged to activate the one or more MOSFETS, the high-power consumption sets the switch protection circuit to pass the input voltage to the switch hot, whereby, completing power to the load. In this way, the power supply board may mitigate the risk of a reverse-wired lead and switch hot, from the input voltage source to the power supply board, by preventing the second capacitor from being charged when the lead and switch hot are connected to the input voltage circuit in reverse.

In another illustrative example, a method of controlling a 120V AC input voltage source to a power supply board, and running a corresponding microcontroller to choose a duty cycle of a corresponding switch protection circuit, is envisioned wherein the switch protection circuit comprises one or more metal-oxide semiconductor field-effect transistors (MOSFETS) of a high-power consumption switch. The method comprises that acts of: supplying cycles of AC input voltage; and controlling the timing for activating the MOSFETS of the high-power consumption switch, via a microcontroller configured to control the load. In this way, the controlled-timing activating of the MOSFETS is configured to occur during a period of low voltage pressure on a negative side of an AC input voltage sine wave.

A complete understanding of the present invention may be obtained by reference to the accompanying drawings, when considered in conjunction with the subsequent, detailed description of preferred embodiments in which like elements and components bear the same designations and numbering throughout the figures.

### BRIEF DESCRIPTION OF THE DRAWINGS

Specific embodiments of the present invention will be described with reference to the following drawings, wherein:

FIG. 1 is a block diagram of the functional components of an exemplary embodiment of a light controller system.

FIG. 2 is a perspective view of an exemplary embodiment of a real-world application of the light controller system of FIG. 1.

FIG. 3 is a partial wiring diagram of an exemplary embodiment of the light controller system of FIG. 1.

FIG. 4 is a partial wiring diagram of an exemplary embodiment of a power supply board to help illustrate the deficiencies in the art.

FIG. 5 is a block diagram of the functional components of an exemplary embodiment of a light controller system of the present invention.

FIG. 6 is a front perspective view of an exemplary embodiment of a real-world application of a light controller system of the present invention.

FIG. 7 is a rear perspective view of the light controller system of FIG. 6.

FIG. 8 is an exploded perspective view of the light controller system of FIG. 6 removed from an indoor electrical box.

FIG. 9 is a perspective view of the light controller system of FIG. 6 in an outdoor electrical box.

FIG. 10 is a front view of the light controller system of FIG. 6.

FIG. 11 is a first partial wiring detail of the light controller system of FIG. 6.

FIG. 12 is a second partial wiring detail of the light controller system of FIG. 6.

FIG. 13 is a magnified portion of a wiring diagram for an exemplary embodiment of an improved power supply board.

FIG. 14A is a first magnified portion of a complete wiring diagram for an improved power supply board, and peripheral and related circuitry including a ZCD module.

FIG. 14B is a second magnified portion of a complete wiring diagram for an improved power supply board, and peripheral and related circuitry including a ZCD module.

FIG. 15A is a first magnified portion of a complete wiring diagram of an exemplary embodiment of an improved user interface board and peripheral and related circuitry including how it partially relates to the power supply board of FIGS. 13-14.

FIG. 15B is a second magnified portion of a complete wiring diagram of an exemplary embodiment of an improved user interface board and peripheral and related circuitry including how it partially relates to the power supply board of FIGS. 13-14.

FIG. 15C is a third magnified portion of a complete wiring diagram of an exemplary embodiment of an improved user interface board and peripheral and related circuitry including how it partially relates to the power supply board of FIGS. 13-14.

FIG. 15D is a fourth magnified portion of a complete wiring diagram of an exemplary embodiment of an improved user interface board and peripheral and related circuitry including how it partially relates to the power supply board of FIGS. 13-14.

FIG. 16 is a complete view a sine wave diagram for an exemplary embodiment of the present invention.

FIG. 17 is a perspective view of an exemplary embodiment of the front of a physical PCB board structure representative of the power supply board of FIGS. 13 and 14.

FIG. 18 is a perspective view of an exemplary embodiment of the rear of the physical PCB board structure representative of the power supply board of FIG. 17.

FIG. 19 is a perspective view of an exemplary embodiment of the front of a physical PCB board structure representative of the user interface board of FIGS. 15A-D.

### DETAILED DESCRIPTION OF PREFERRED EMBODIMENTS

The following preferred embodiments, as exemplified by the drawings, are illustrative of the invention and are not intended to limit the invention as encompassed by the claims of this application.

Embodiments and aspects of the present invention provide a power supply driver circuit, and method of controlling the same, for the lighting array of a pool, spa, or landscape thereof. The power supply board may be integral to a unitary and dedicated controller for the lighting array, but is not limited to such an embodiment. The lighting array may comprise a series of interconnected LED lighting products, such as non-networked LED lighting devices and products known in the art and available from known suppliers and manufacturers, or equivalent, with or without sync adapters, etc.

Unlike the relevant prior art power-supply boards, the power supply board of the present disclosure substantially mitigates the risk of a reverse-wired lead and switch hot from the power source to the power supply board. In one exemplary embodiment, the present disclosure provides a power supply board (and a final, resulting LED controller) configured to be structurally adapted to control the load via a microcontroller and a high-power consumption switch, and to turn on and off the 120V AC power source with any duty cycle, wherein the timing at which the switch is activated is controlled to occur during a period of low voltage pressure on the negative side of the AC input voltage sine wave. The present invention preferably provides these features without compromising the competing functions of the power supply board and/or the resulting LED controller.

For example, the power supply board of the present disclosure substantially mitigates the risk of a reverse-wired lead and switch hot to the power supply board, without compromising the following functions: (1) the capability of the power supply board to monitor an operating power source; (2) the capability of the power supply board to generate a low-voltage DC signal to power the electronic components driven off of the power supply board (such as a microcontroller, communication system, sensor array, [e.g., motion sensors, ambient light sensors, temperature sensors], gate drivers, etc.) even when the light of the lighting array is turned off; and (3) the capability of the power supply board to provide power to a high brightness lighting array in an efficient manner (i.e., to efficiently drive a high voltage, high current load, to the array of LEDs).

Accordingly, the power supply board of the present disclosure may, instead of completely being turned off, still be put into a standby mode in which the lights are off, but some of the electronic components remain on. Further, the power supply board may continue to include a power conversion component configured to operate as active, in which output power is supplied to the load, or as standby, and in which output power is not supplied to the load.

In another exemplary embodiment, at a very high-level, the present disclosure provides a power supply board (and a final, resulting LED controller) wherein a metal-oxide semiconductor field-effect transistor (MOSFET) switch is used as a circuit protection means. The MOSFET switch protection circuit combines an LNK switch, a voltage regulation circuit, and a LPC11E67JBD48 microcontroller, for example, including software programmed inside the microcontroller chip to realize the mis-wire protection of hot wire and switch hot wire (SW Hot). In particular, the MOSFET switch circuit prevents system boot-up when the hot wire and switch hot wire are connected in reverse. When the hot wire and the switch hot are correctly connected, the AC sine wave positive and negative are correctly passed through the MOSFET switch circuit to the switch hot to power the lights connected to the load.

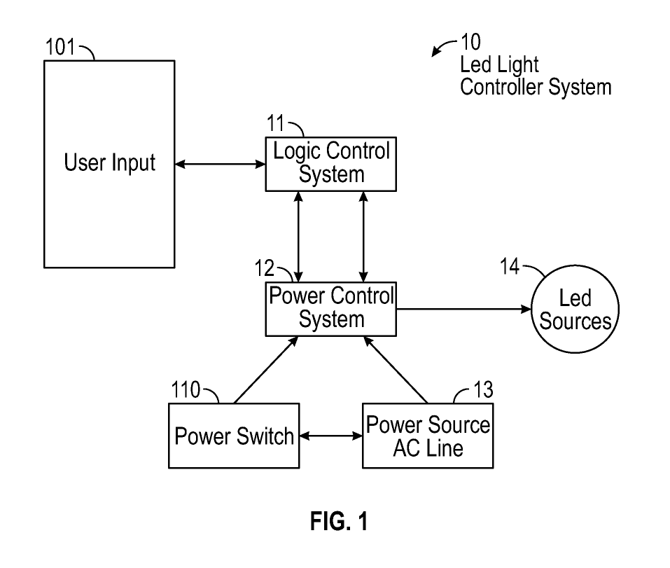

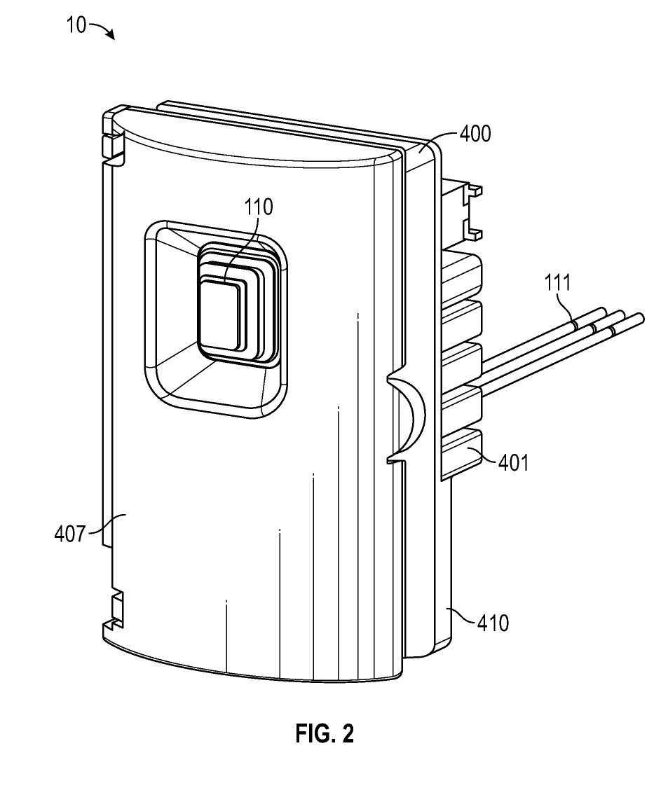

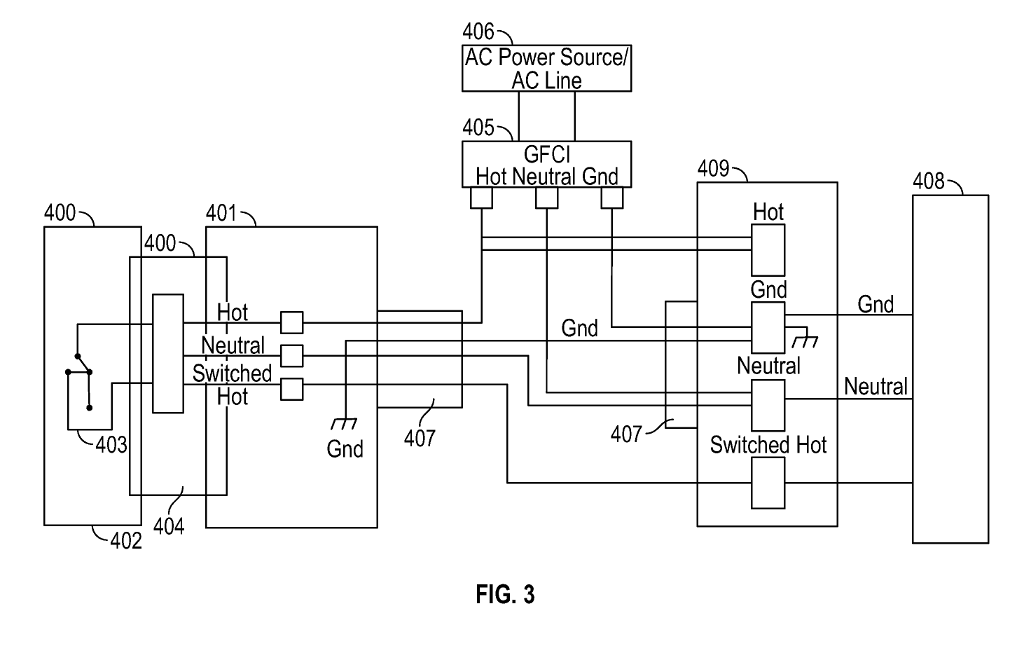

Now, with that context, attention is turned to the fundamental architecture of certain power supply boards for a light controller system. As is shown in FIG. 1, an exemplary embodiment of a light controller system 10 is broken down into functional components. In FIG. 2, the light controller system 10 is shown in one exemplary embodiment of a real-world application. The light controller system 10 is shown in a standard outlet/switch box 410 mounted on a wall box 401 containing electronic components/circuit boards as well as a rotary switch (not shown in FIG. 1, see FIG. 3) for a user. A multitude of light shows can be represented on a faceplate on the box on a display 110. The user can align the rotary switch to a specific light show representation on the faceplate display 110. The light controller system 10 can set the selection from the user, and output the specific light show by controlling the circuitry.

More specifically, the light controller system 10 comprises—in terms of functional components—a user input 101, a power switch 110 (in the form of power switch 403 in FIG. 3), a logic control system 11, a power control system 12, an AC power source (e.g., AC main line) 13, and LED array 14. In one exemplary embodiment, these components can be connected as shown by arrows in FIG. 1; however, other configurations are possible. The LED array 14 comprises LED pool, spa, and/or landscape lights, or any other LED sources capable of light-output control in the form of fixed-color or multi-colored shows. The LED sources 14 can be 120-volt (V) lights with a 1:1 transformer, or 12V lights including a step-down transformer. The AC line 13 can be connected to the power control system 12 through a ground fault circuit interrupter (GFCI) (in the form of GFCI 405 in FIG. 3) as the source of power to a portion of the entire LED light controller system 10, including the power control system 12, the logic control system 11, and the LED array 14. In addition, the power switch 110 can be connected to the power control system 12 to selectively provide or remove power to the light controller system 10. If the light controller system 10 is on (e.g., the power switch 110 is enabled), specific color show information from the user input 101 can be received and processed by the logic control system 11 (and depicted to the user in the form of display 110 in FIG. 2). The logic control system 11 can then output specific voltage pulses to signal the power control system 12 to the LED array 14.

In particular, one exemplary embodiment of the logic controller 11 comprises a faceplate indicating the light shows available to select from. The faceplate includes a selector, such as a rotary switch, positioned to select one of the light shows. The system also includes a microcontroller with processor(s) in communication with the selector, wherein the processor(s) is configured to execute a program to control the color-changing lighting effect generated by the lighting apparatus, and to synchronize the color-changing lighting effect in coordination with a parameter of the operating power source. In certain embodiments, the timing of the program execution may be coordinated with the frequency of the AC power, voltage or current. Further, the logic controller 11 may coordinate the lighting effect with a transient parameter of the power source or other randomly, periodically or otherwise occurring parameter of the power source. This provides for a synchronized lighting effect without the need for network communication, for example.

Turning to FIG. 3, the functional components of the light controller system 10 are shown in an exemplary structural embodiment. The wiring diagram for an LED light controller system 400 shows that the system can be housed within a metal gang box 401. A front panel 402 on the gang box 401 can include a power switch 403, like the power switch 110 of FIG. 1, to control power to the LED light controller system 400. The power switch 403 can be connected to a power control system 404, which is like the power control system 12 of FIG. 1. The power control system 404 can receive power from a GFCI 405. Power to the GFCI 405 can come from an AC power source (AC line) 406. Wire connections 111 (see FIG. 2) can be protected by a rigid or PVC conduit 407. Further, the power control system 404 can be connected to a LED array 408, like the LED array 14 of FIG. 1, via a junction box 409.

A person having ordinary skill in the art readily understands that, once the switch 403 has been depressed, a hot voltage wire from the GFCI 405 can be in connection with the switch hot voltage wire, thus providing voltage to the LED array 408. The power control system 404 also can, via a logic control system 11 like that of FIG. 1, modulate the AC voltage on the switch hot voltage wire to provide pulses to the plurality of LED sources 408. Decode circuitry within the LED array 408 components can process the number of pulses received and output a corresponding light show, for example. Of course, in certain instances, the number of pulses provided can be determined by the logic control system 11 from a user input 101 (see FIG. 1) via the display 402.

As a practical matter, in this one example, as in other examples, there is a risk that a user might reverse the wiring of the lead (hot) and the sw hot of the LED light controller system 400, for example, which may cause damage to the rest of the electrical components off of power control system 404, and which may create hazard to the user and those around the system.

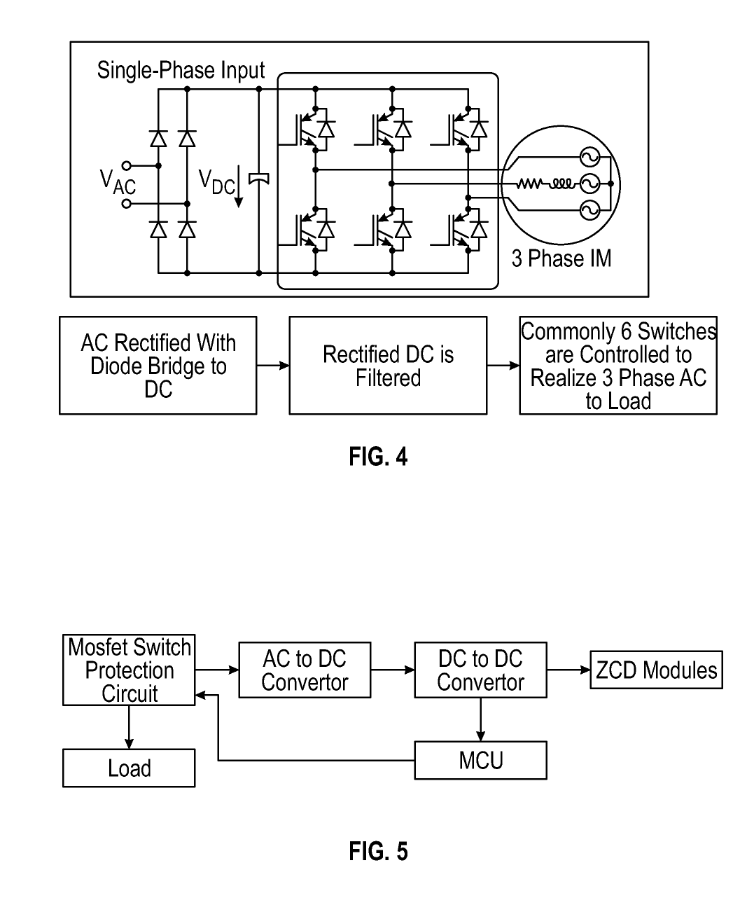

FIG. 4 shows an exemplary embodiment of a portion of a wiring diagram, for a common power supply embodiment, to help illustrate the source of problem for the deficiency in the art. As is shown, common AC control is used in the three-phase AC generation, wherein AC is rectified, via a diode bridge, into DC and noise is filtered out of the rectified signal. Then DC is used to generate three-phase power, via a six (6) switch set-up, which is controlled by relays or micro-controllers (for example, but not limited, to those of the logic control system 11).

A person having ordinary skill in the art understands that human error is likely to happen and that preemptively correcting for such errors is good business. As such, embodiments and aspects of the present invention provide for an LED controller and, in particular, a power supply board that can solve these issues and balance the competing functions described herein.

Turning again to the figures, one or more of the above objects can be achieved, at least in part, by providing a modified light controller system as disclosed herein. An exemplary embodiment of a standard light controller system 10 and 400 are shown in FIGS. 1-4. With this background in mind, exemplary embodiments of an improved light controller system and, in particular, an improved power supply board will next be disclosed. While the newly disclosed embodiments share certain structural features with the exemplary light controller systems of FIGS. 1-4, the distinctions and alterations will become apparent to one of ordinary skill in the art upon reading the following additional disclosure.

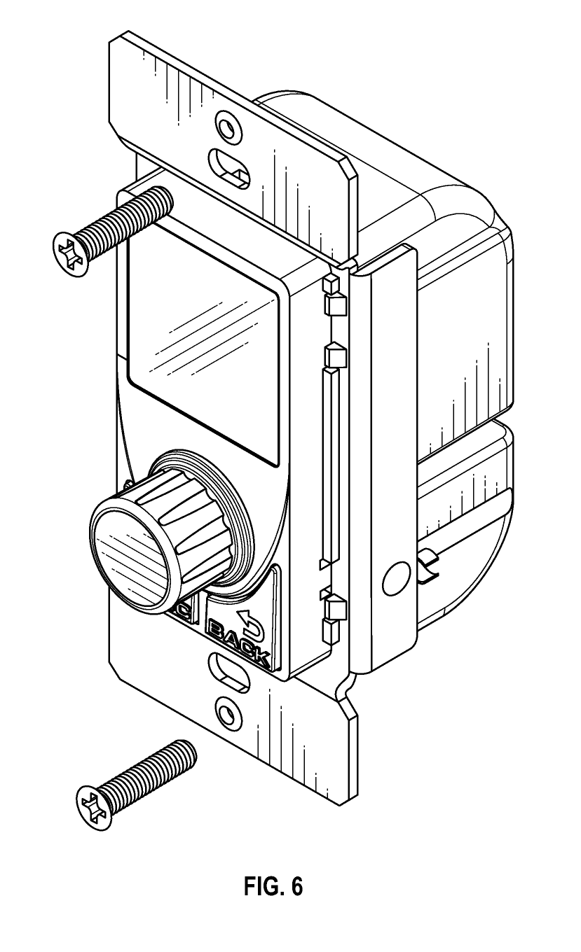

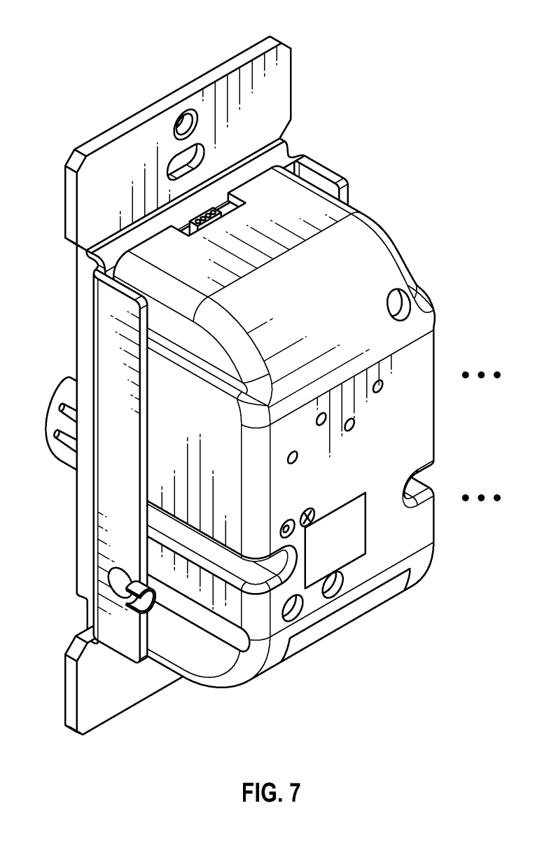

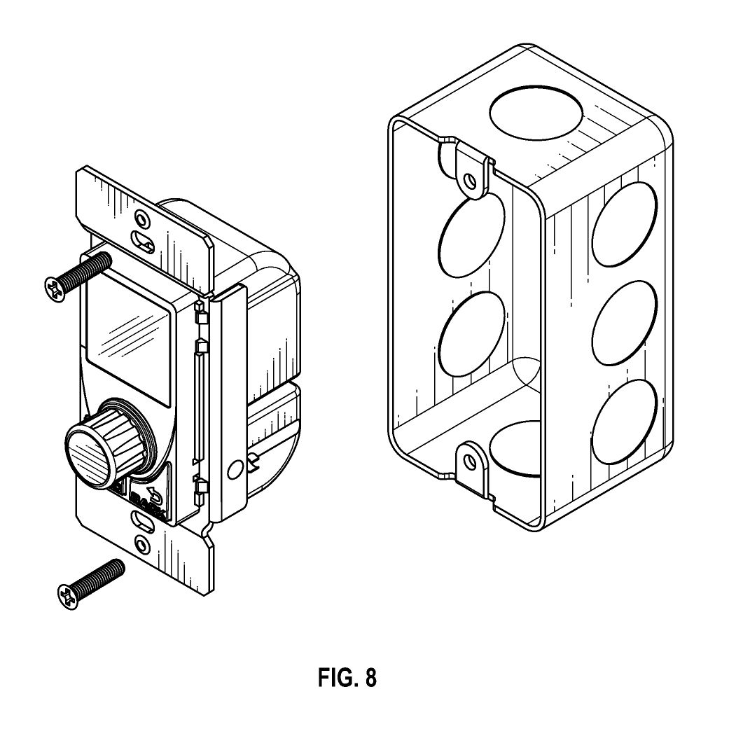

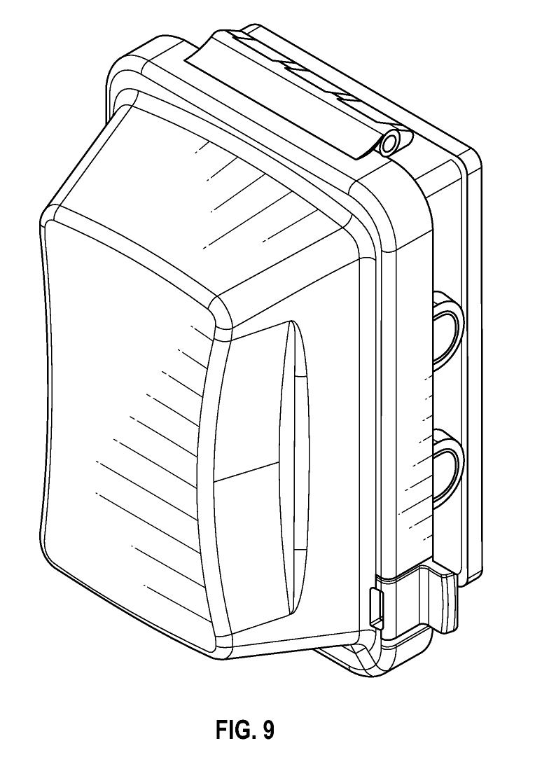

As is shown in FIG. 5, an exemplary embodiment of an improved light controller system of the present invention is broken down into functional components. In FIGS. 6-9, the light controller system 100 is shown in one exemplary embodiment of a real-world use. The light controller system 100 may be placed in a single or double gang (single gang, minimum 18 in³ volume with a minimum 2 in depth, for example, as shown in FIG. 8) indoor electrical box or a single or multi-gang outdoor electrical box (single, for example, as shown in FIG. 9). The light controller system 100 can function as a dedicated solution for controlling pool and spa LED lighting from a convenient remote location. Further, the control 100 is designed to be wired to a lighting transformer as needed (best seen in FIG. 11).

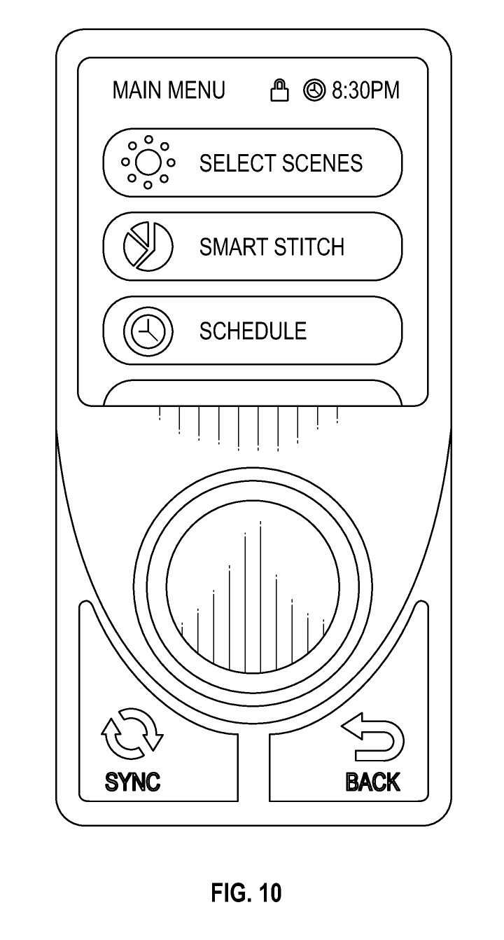

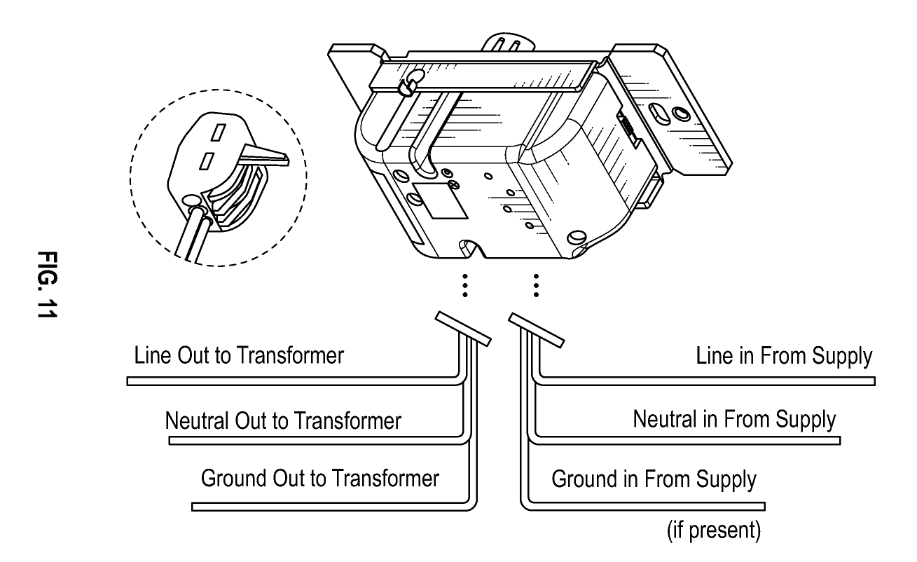

As is shown in FIG. 10, once installed, the control 100 may be used to fully control pool and spa lighting load, and a full color LCD display A, for example, may be used to access all functionality of the control 100. Further, an analog rotary dial switch B may be used to interact with all options on the LCD screen A, by turning to move the cursor and pushing to select. This may result in the following commands: turn lights on/off, select and customize light shows and colors, set schedules, and lock down the control, for example. As other non-limiting examples, a back button D may be pressed to go back one screen inside the control menus, and a sync button E may be pressed to automatically synchronize all attached and compatible LED lights as the load, as well as other input features known in the art.

More specifically, the light controller system 100 comprises—in terms of functional components—a logic control microcontroller (MCU), a high power consumption switch in the form of a MOSFET switch protection circuit, an AC to DC convertor, a DC to DC convertor, a zero cross detect (ZCD) module, and a load (without repeating basic functional blocks like an AC power source, a user input, and a GFCI, as previously described herein). In one exemplary embodiment, these components are connected as shown by arrows in FIG. 5; however, other configurations are possible.

In a preferred embodiment, the load may be an LED array and the LED array may comprise a 120 volt (V) lights with a 1:1 transformer, or 12V lights including a step-down transformer (best seen in FIG. 11). The system 100 may handle a total allowable light wattage of 300 watts and run 2.50 amperes. An example of several possible combinations of lighting capable of being handled as the load include: (1) twenty-two 11 W 1.5″ LED lights; (2) twelve 11 W 1.5″ LED lights, seven LED laminar features and twelve feet of LED waterfall features; and (3) six 11 W 1.5″ LED lights, three LED laminar features, three LED bubbler features, six 4″ LED bubbler features and nine feet of LED waterfall features.

Further, the MOSFET switch circuit may be used as a circuit protection method for the overall light controller system 100. In this way, the MOSFET switch protection circuit may combine an LNK switch, voltage regulation circuit and LPC11E67JBD48 microcontroller including software programmed inside the microcontroller chip, for example, to realize a mis-wire protection for a hot wire and sw hot. The MOSFET switch circuit also may prevent system 100 boot up when a hot wire and a sw hot wire are reversed connected in the field in a hazardous water setting.

As is previously explained, when a hot wire and a sw hot wire are connected correctly to the system 100, the AC sine wave positive and negative are correctly passed through the MOSFET switch circuit to the sw hot to power the load. However, in the inventive embodiment, as is understood by a person having ordinary skill in the art, the first half signal of the AC sine wave is allowed to come through (usually through the Neutral wire), to charge down-stream capacitors, and completing the circuit, which allows further charging of capacitors, and activation of switches, and so on. Therefore, when a hot wire and sw hot wire are reverse-connected, there is no complete circuit and no further signal to the load.

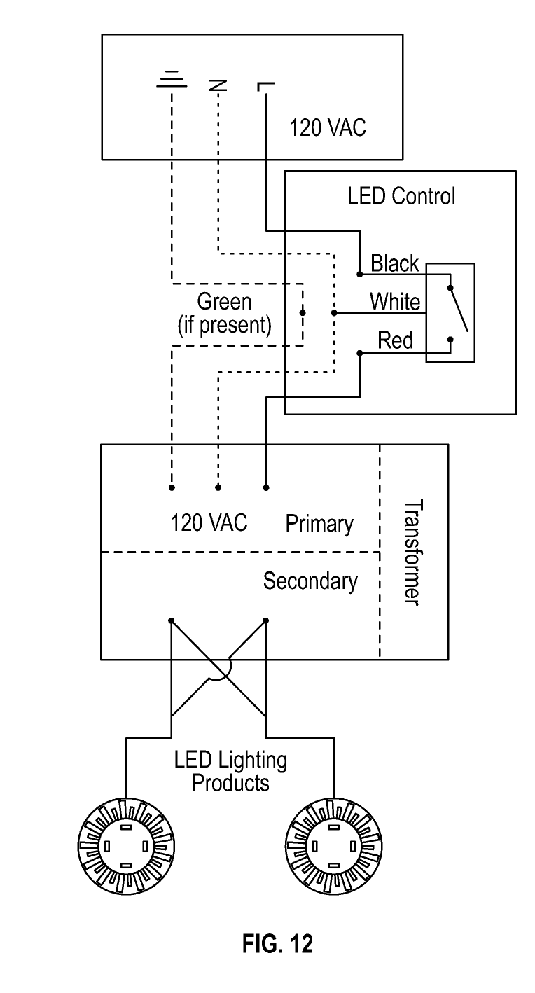

Turning to FIG. 11, the functional components of the light controller system 100 are shown in an exemplary structural embodiment. The wiring diagram for an LED light controller system 100 shows that the White is configured as a Neutral in from the power supply and Out to a transformer, shows that the Red is configured as a Line out to the transformer, shows that the Black is configured as a Line in from the power supply; and shows that the Green is configured as a Ground in from the power supply and out to the transformer. If no Ground is necessary, required, or present, then the Green wire is left unconnected and with cap on). Additional details are presented in the control wiring detail, for one exemplary embodiment, shown in FIG. 12.

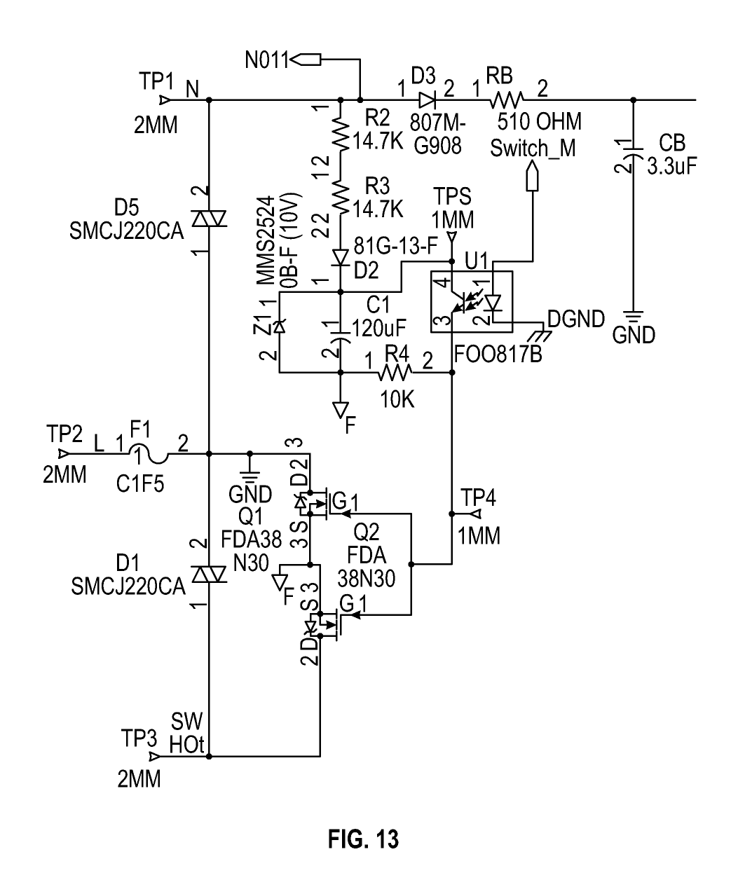

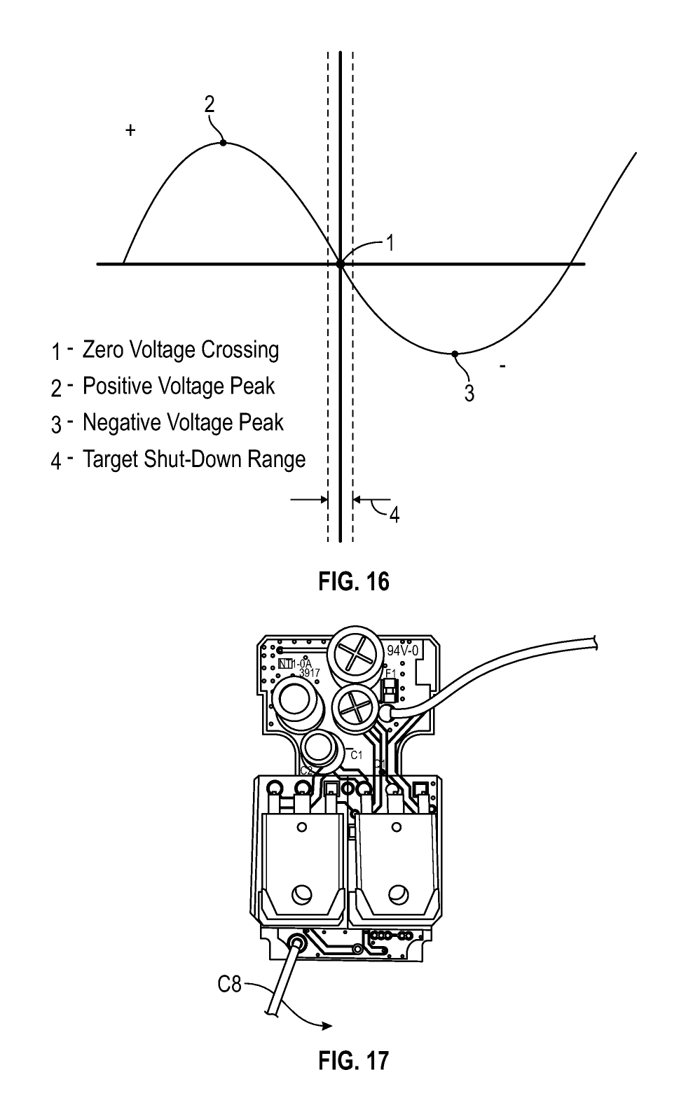

FIGS. 13-15 show an exemplary embodiment of a portion of a wiring diagram, for an improved common power supply embodiment 100, and peripheral and related circuitry including a user interface board. The corresponding sine wave diagram is shown in FIG. 16. An exemplary embodiment of a physical PCB board structure(s) representative of the exemplary wiring diagrams of FIGS. 13-15 are shown in FIGS. 17-19.

As is shown, and understood by a person having ordinary skill in the art, a load can be controlled by a microcontroller (MCU) to turn on and off the 120V AC with any duty cycle. The timing at which the switch is activated is controlled to occur during a period of low voltage pressure on the negative side of the AC input voltage sine wave, as seen in FIG. 16.

Specifically, in this exemplary embodiment, capacitors C1 and C8 are charged in a first cycle of the AC input voltage sine wave. Further, C8 sends power to the MCU. Further, the MCU sends the signal to a Switch M to turn on an optocoupler U1. Further, C1 discharges to turn on MOSFET Q1 and MOSFET Q2. Further, the AC can be controlled by the MCU to choose the duty cycle of Q1/Q2, as desired. In application, this results in Q1 and Q2 being turned on to pass AC power to the sw hot line and completing power to the load. As such, the circuit is designed such that if the system 100 is wired in reverse, the product will not turn on preventing damage to the electrical components and potential injury to the operator. Further, if the sw hot and hot are connected in reverse, C8 cannot be successfully charged, as power cannot complete the loop to the Neutral line.

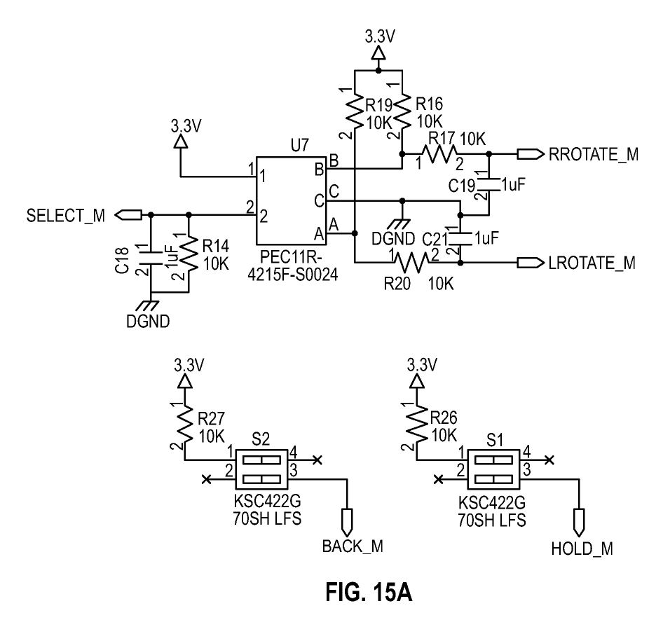

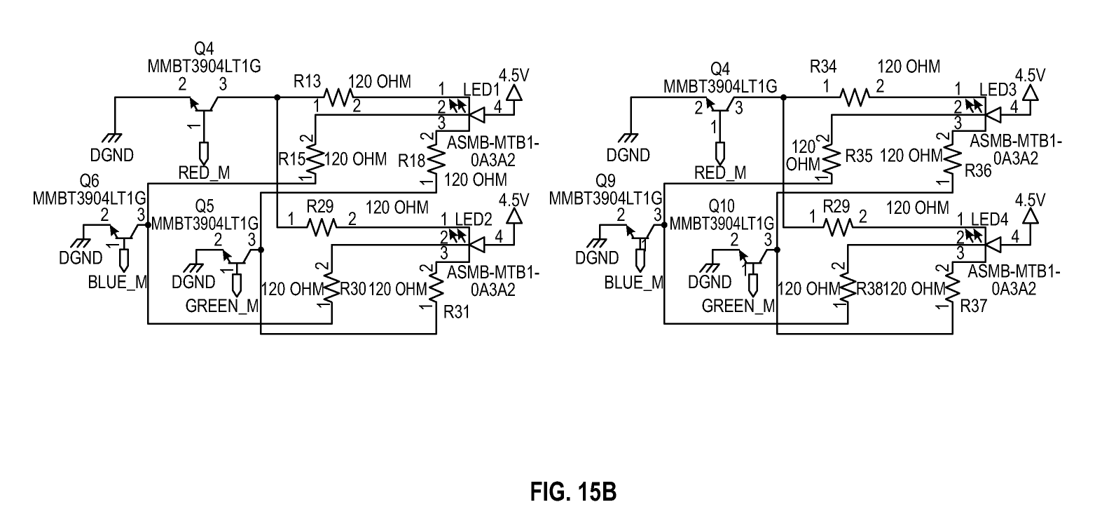

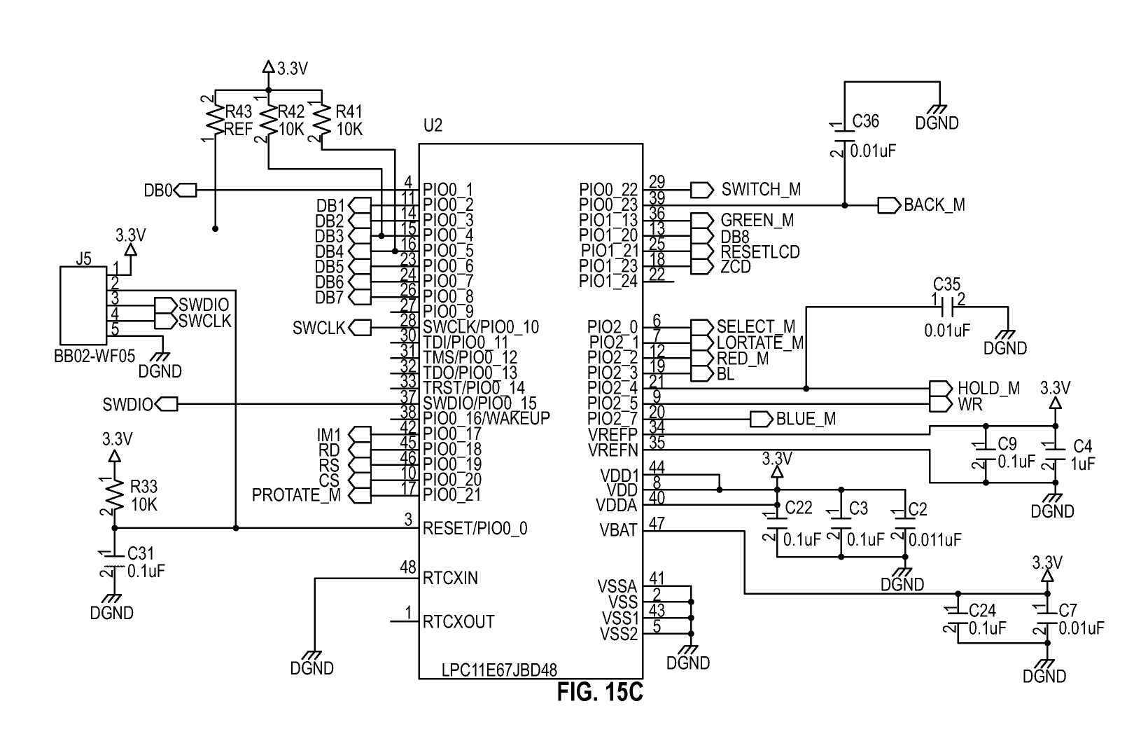

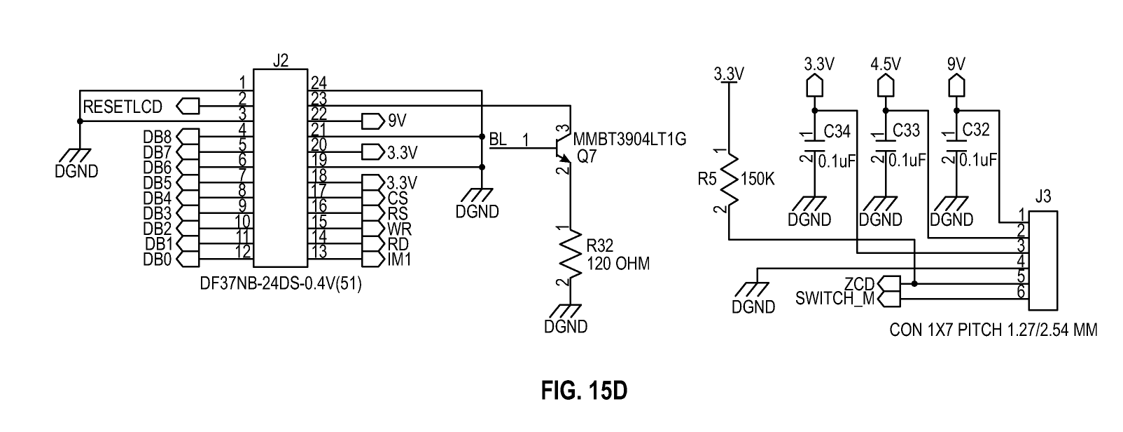

Said another way, and for a different perspective, with reference to the sine wave diagram of FIG. 16, a first half signal of AC sine wave comes from a Neutral wire, it charges capacitor C1, by passing parasite diode of MOSFET 5, and goes back to hot wire 8. At the same time, a first half cycle of AC sine wave charges capacitor C8 and goes back to hot wire 8. After the capacitor C8 is charged, an LNK switch, for example, is activated and powers the microcontroller on a user-interface board (best seen in FIGS. 15A-D). The microcontroller gives signal to a Switch M to turn on an optocoupler U1. As such, energy stored in capacitor C1, passes optocoupler U1 to turn on MOSFET Q1 and MOSFET Q2 to prepare the process of a second cycle of sine wave.

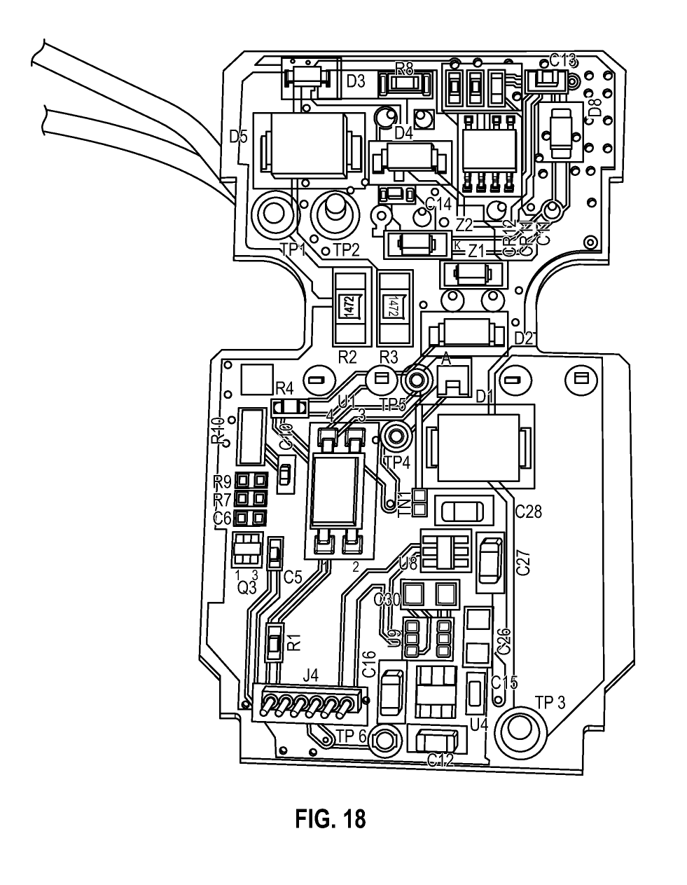

Therefore, when a hot wire and sw hot wire are reversed connected, there is no complete loop for the capacitor C8 path. As a result, capacitor C8 cannot be charged to turn on the LNK switch and microcontroller (MCU), and there is no signal on signal-pad Switch M. The complete loop for turning on optocoupler U1, MOSFET Q1 and MOSFET Q2 is not finished, and there is no power going to the load. It is recognized for this exemplary embodiment that the improved system 100 relies on a high-power consumption switch in the form of the configured and structured MOSFETS (especially in high power set ups) and that this may result in possible thermal issues on the power supply board and surrounding circuitry. Therefore, for this embodiment, a heat sink in thermal communication with the high-power consumption switch/MOSFETS is necessary. It also is envisioned that such a heat sink may be attached near or around the MOSFET on an exemplary PCB board, as seen in FIGS. 17 and 18.

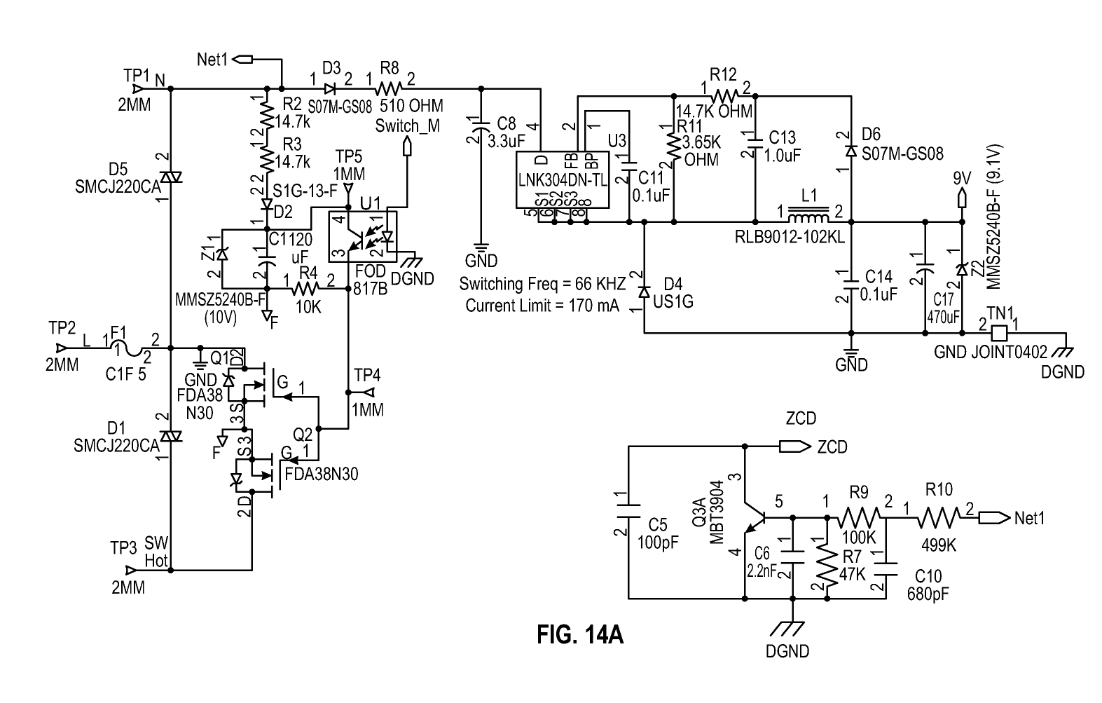

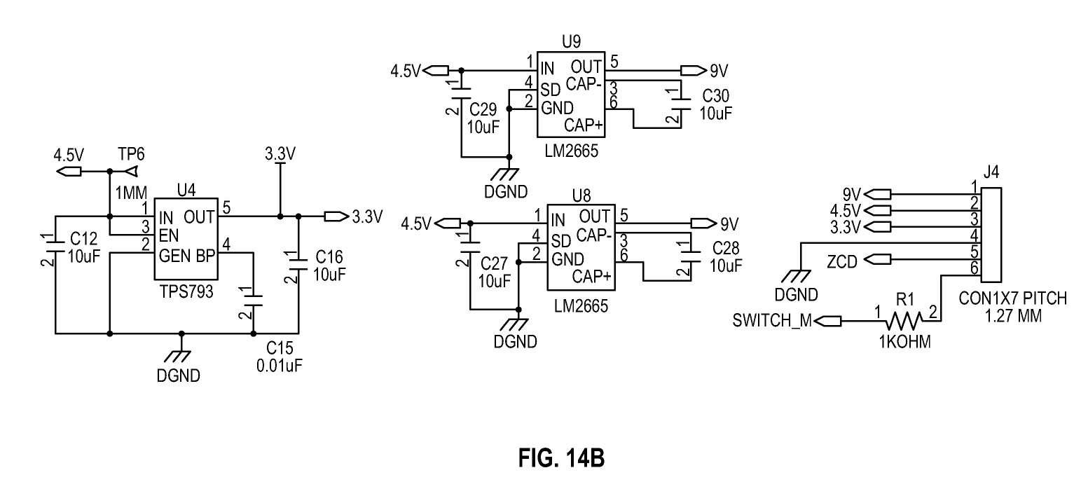

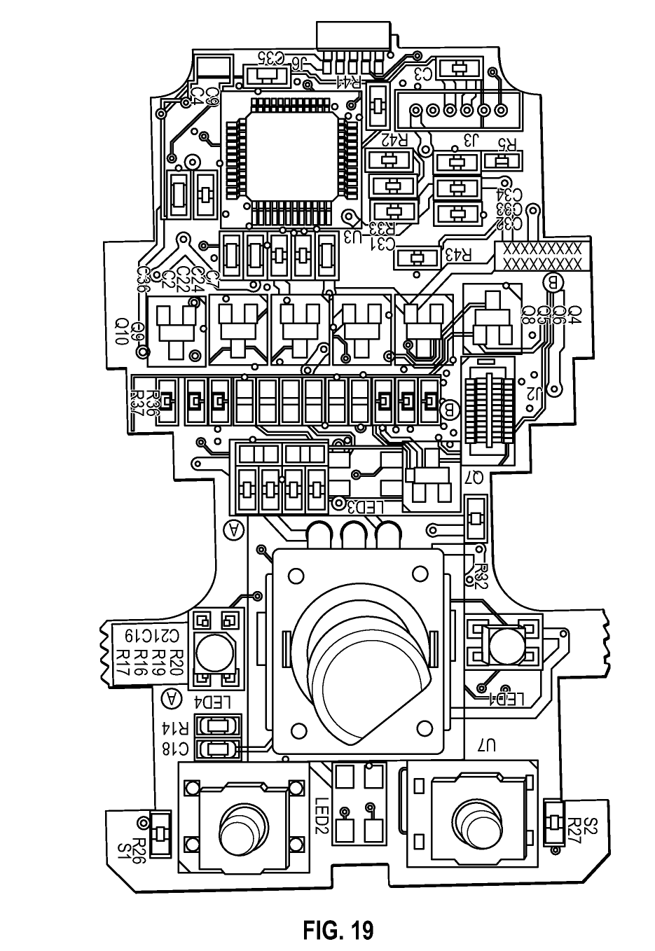

Turning to FIG. 17, the figure shows the front of an exemplary embodiment of a physical PCB board structure representative of the power supply board of FIGS. 13 and 14. Similarly, FIG. 18 shows the back of the exemplary physical PCB board structure of FIG. 17. FIG. 19 shows the front of an exemplary embodiment of a physical PCB board structure representative of the user interface board of FIGS. 15A-D.

The above detailed description of the embodiments are for illustrative purposes only and are not intended to limit the scope and spirit of the invention, and its equivalents, as defined by the appended claims. One skilled in the art will recognize that many variations can be made to the invention disclosed in this specification without departing from the scope and spirit of the invention. Further modifications of the present invention will occur to persons skilled in the art. All such modifications are deemed to be within the scope and spirit of the present invention as defined by the appended claims.

What is claimed is:

1. A power supply board of a light controller system, for a pool or spa-lighting application, that can turn on/off a 120V AC input voltage source with any duty cycle, the power supply board comprising:
a) an input voltage circuit;
b) a load output circuit;
c) a microcontroller;
d) a high-power consumption switch comprising one or more metal-oxide semiconductor field-effect transistors (MOSFETS); and
e) a heat sink;
wherein the microcontroller is configured to control the load, via activation of the MOSFETS of the high-power consumption switch, as a switch protection circuit;
wherein the timing at which the MOSFETS are activated is controlled to occur during a period of low voltage pressure on a negative side of an AC input voltage sine wave; and
wherein the heat sink is in direct thermal communication with the high power consumption switch.

2. The power supply of claim 1, wherein the high-power consumption switch comprises at most two MOSFETS.

3. The power supply of claim 1:
wherein the power supply board mitigates the risk of a reverse-wired lead and switch hot, from the input voltage source to the power supply board, by preventing boot-up of a light controller system when the lead and switch hot are connected to the input voltage circuit in reverse; and
wherein, when the lead and the switch hot are not connected in reverse, the AC input sine wave positive and negative are correctly passed through the MOSFETS of the high-power consumption switch to the switch hot to the load.

4. The power supply of claim 3, additionally comprising:
f) an AC to DC convertor circuit; and
g) a DC to DC convertor circuit.

5. The power supply of claim 3, additionally comprising:
h) a zero cross detect (ZCD) module.

6. The power supply of claim 3, additionally comprising:
f) a first capacitor and a second capacitor;
wherein, when the lead and the switch hot are not connected in reverse, the first capacitor is charged in a first half signal of the AC input voltage sine wave, passing a parasitic diode of a first of the one or more MOSFETS;
wherein, when the lead and the switch hot are not connected in reverse, the second capacitor is charged in a first cycle of the AC input voltage sine wave;
wherein the first capacitor is communicatively coupled to the one or more MOSFETS and configured to activate the one or more MOSFETS; and
wherein the second capacitor is communicatively coupled to the microcontroller, for running the microcontroller to choose a duty cycle of the one or more MOSFETS, to prepare to process a second cycle of the AC input sine wave.

7. The power supply of claim 6:
wherein, when the first capacitor is discharged to activate the one or more MOSFETS, the high-power consumption sets the switch protection circuit to pass the input voltage to the switch hot, whereby, completing power to the load; and
wherein the power supply board mitigates the risk of a reverse-wired lead and switch hot, from the input voltage source to the power supply board, by preventing the second capacitor from being charged when the lead and switch hot are connected to the input voltage circuit in reverse.

8. A power supply board of a light controller system, for a pool or spa-lighting application, that can turn on/off a 120V AC input voltage source with any duty cycle, the power supply board comprising:
a) an input voltage circuit;
b) a load output circuit;
c) a microcontroller;
d) a high-power consumption switch comprising one or more metal-oxide semiconductor field-effect transistors (MOSFETS);
e) a heat sink; and
f) a first capacitor and a second capacitor
wherein the microcontroller is configured to control the load, via activation of the MOSFETS of the high-power consumption switch, as a switch protection circuit;
wherein the timing at which the MOSFETS are activated is controlled to occur during a period of low voltage pressure on a negative side of an AC input voltage sine wave;
wherein the first capacitor is charged in a first half signal of the AC input voltage sine wave;
wherein the second capacitor is charged in a first cycle of the AC input voltage sine wave;
wherein the first capacitor is communicatively coupled to the one or more MOSFETS and configured to activate the one or more MOSFETS;
wherein the second capacitor is communicatively coupled to the microcontroller, for running the microcontroller to choose a duty cycle of the one or more MOSFETS, to prepare to process a second cycle of the AC input sine wave; and
wherein the heat sink is in direct thermal communication with the high power consumption switch.

9. The power supply of claim 8, wherein the high-power consumption switch comprises at most two MOSFETS.

10. The power supply of claim 8:
wherein the power supply board mitigates the risk of a reverse-wired lead and switch hot, from the input voltage source to the power supply board, by preventing boot-up of a light controller system when the lead and switch hot are connected to the input voltage circuit in reverse; and
wherein, when the lead and the switch hot are not connected in reverse, the AC input sine wave positive and negative are correctly passed through the MOSFETS of the high-power consumption switch to the switch hot to the load.

11. The power supply of claim 10, additionally comprising:
f) an AC to DC convertor circuit; and
g) a DC to DC convertor circuit.

12. The power supply of claim 11, additionally comprising:
h) a zero cross detect (ZCD) module.

13. The power supply of claim 10:
wherein, when the first capacitor is discharged to activate the one or more MOSFETS, the high-power consumption sets the switch protection circuit to pass the input voltage to the switch hot, whereby, completing power to the load; and
wherein the power supply board mitigates the risk of a reverse-wired lead and switch hot, from the input voltage source to the power supply board, by preventing the second capacitor from being charged when the lead and switch hot are connected to the input voltage circuit in reverse.

14. A method of controlling a 120V AC input voltage source to a power supply board, and running a corresponding microcontroller to choose a duty cycle of a corresponding switch protection circuit, wherein the switch protection circuit comprises one or more metal-oxide semiconductor field-effect transistors (MOSFETS) of a high-power consumption switch, the method comprising that acts of:
(1) supplying cycles of AC input voltage; and
(2) controlling the timing for activating the MOSFETS of the high-power consumption switch, via a microcontroller configured to control the load, the controlled-timing activating the MOSFETS to occur during a period of low voltage pressure on a negative side of an AC input voltage sine wave.
